(19) United States
(12) Patent Application Publication
(10) Pub. No.: US 2013/0235570 A1
(43) Pub. Date: Sep. 12, 2013

(54) Light emitting device with two linear light emitting sections

(71) Applicants: William Hood, Northbrook, IL (US); Liangfu Zhou, Lincolnshire, IL (US)

(72) Inventors: William Hood, Northbrook, IL (US); Liangfu Zhou, Lincolnshire, IL (US)

(73) Assignee: LED Lighting Inc., Northbrook, IL (US)

(21) Appl. No.: 13/796,709

(22) Filed: Mar. 12, 2013

Related U.S. Application Data
(60) Provisional application No. 61/609,392, filed on Mar. 12, 2012.

(51) Int. Cl. F21V 21/00; H05K 13/04

(52) U.S. Cl. CPC F21V 21/00; H05K 13/04
USPC 362/225; 29/830

(57) ABSTRACT

In one embodiment, a light emitting device comprises two tubes comprising linear arrays of light emitting diodes physically coupled by a third tube. In one embodiment, the third tube comprises a linear array of light emitting diodes. In another embodiment, the first tube, second tube, and third tube of the light emitting device are positioned to substantially form the shape of a character “U” in a plane perpendicular to the optical axis. In another embodiment, the first linear array of light emitting diodes has an average spacing between the light emitting diodes, and a ratio of the first, shorter dimension of the light emitting diodes to the average spacing is between 1 and 3.

### BACKGROUND

The subject matter disclosed herein generally relates to light emitting devices such as light fixtures, light bulbs, replacement light bulbs, devices comprising light emitting diodes, and their components and method of manufacture. Light emitting devices are needed which are thinner, lighter weight, replaceable, cheaper to manufacture, scalable to large sizes, and have replaceable components.

### BRIEF DESCRIPTION OF THE DRAWINGS

FIG. 1 is a bottom view of an embodiment of a light emitting device in the form of a U-shaped LED tube comprising an arcuate light emitting region positioned between two linear light emitting regions.

FIG. 2 is a bottom view of a portion of the linear light emitting region of the light emitting device of FIG. 1.

FIG. 3 is a cross-sectional view of the light emitting device of FIG. 1 with the light transmitting cover unattached.

FIG. 4 is a cross sectional view of the light emitting device of FIG. 1 with the light transmitting cover attached.

FIG. 5 is a perspective view of an embodiment of a secure and removable connector means for connecting a first plurality of leads for a light emitting device.

FIG. 6 is a bottom view of an embodiment of a light emitting device comprising three linear light emitting regions.

### DETAILED DESCRIPTION OF THE INVENTION

The features and other details of several embodiments will now be more particularly described. It will be understood that particular embodiments described herein are shown by way of illustration and not as limitations. The principal features can be employed in various embodiments without departing from the scope of any particular embodiment. The present inventive subject matter now will be described more fully hereinafter with reference to the accompanying drawings, in which embodiments of the inventive subject matter are shown. However, this inventive subject matter should not be construed as limited to the embodiments set forth herein. Rather, these embodiments are provided so that this disclosure will be thorough and complete, and will fully convey the scope of the inventive subject matter to those skilled in the art. Like numbers refer to like elements throughout. As used herein the term “and/or” includes any and all combinations of one or more of the associated listed items.

The terminology used herein is for the purpose of describing particular embodiments only and is not intended to be limiting of the inventive subject matter. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

When an element such as a layer, region or substrate is referred to herein as being “on” or extending “onto” another element, it can be directly on or extend directly onto the other element or intervening elements may also be present. In contrast, when an element is referred to herein as being “directly on” or extending “directly onto” another element, there are no intervening elements present. Also, when an element is referred to herein as being “connected” or “coupled” to another element, it can be directly connected or coupled to the other element or intervening elements may be present. In contrast, when an element is referred to herein as being “directly connected” or “directly coupled” to another element, there are no intervening elements present.

In addition, a statement that a first element is “on” a second element is synonymous with a statement that the second element is “on” the first element.

Although the terms “first”, “second”, etc. may be used herein to describe various elements, components, regions, layers, sections and/or parameters, these elements, components, regions, layers, sections and/or parameters should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive subject matter.

Furthermore, relative terms, such as “lower” or “bottom” and “upper” or “top,” may be used herein to describe one element's relationship to another element as illustrated in the Figures. Such relative terms are intended to encompass different orientations of the device in addition to the orientation depicted in the Figures. For example, if the device in the Figures is turned over, elements described as being on the “lower” or “bottom” side of other elements would then be oriented on the “upper” or “top” sides of the other elements. The exemplary term “lower”, can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

### Light Emitting Device

In one embodiment, a light emitting device comprises two tubes comprising linear arrays of light emitting diodes physically coupled by a third tube. In one embodiment, the third tube comprises a linear array of light emitting diodes. In another embodiment, the first tube, second tube, and third tube of the light emitting device are positioned to substantially form the shape of a character “U” in a plane perpendicular to the optical axis. In another embodiment, an array of light sources disposed on a heat sink or housing substantially in the shape similar to the character “U.” In one embodiment, the light emitting device comprises a curved array of light sources disposed at a pitch such that the light is perceived as a single continuous curve of light by an individual with a visual acuity of 1 arcminute at a distance of 1 meter. In another embodiment, the light sources are an array of Light Emitting Diodes (LEDs) disposed on a circuit board thermally coupled to an aluminum tube heat sink. In one embodiment, a light emitting device comprises a U-shaped array of LEDs disposed on one or more circuit boards wherein the light emitting device is a replacement bulb. In one embodiment, the light emitting device comprises two parallel tube sections operatively coupled to a third tube section oriented orthogonal to the two parallel tube sections.

### Light Source

In one embodiment, a light emitting device comprises an array of two or more light sources. In another embodiment, a curved light emitting device comprises an array of LEDs positioned along a curve and upon one or more circuit boards. In one embodiment, the array of light sources is a curved array with discrete LED packages comprising at least one LED die. In another embodiment, a light emitting device comprises a plurality of light sources within one package disposed to emit light toward a surface for illumination. In one embodiment, the light emitting device comprises at least one selected from the group of: 2, 3, 4, 5, 6, 8, 9, 10, 20, 40, 60, 80, 100, 120, 140, 160, 180, 200, 220, 240, 260, 280, 300, 320, 340, 360, 380, and 400 light emitting diodes. In one embodiment, the dimension, A, of the LED in a linear direction is less than one selected from the group of 10 mm, 8 mm, 6 mm, 5 mm, 4 mm, 3 mm, and 2 mm.

### Spectral Properties of the Light Source

In one embodiment, a light emitting device comprises at least one broadband light source that emits light in a wavelength spectrum larger than 100 nanometers. In another embodiment, a light emitting device comprises at least one narrowband light source that emits light in a narrow bandwidth less than 100 nanometers. In another embodiment, a light emitting device comprises at least one broadband light source that emits light in a wavelength spectrum larger than 100 nanometers or at least one narrowband light source that emits light in a narrow bandwidth less than 100 nanometers. In one embodiment a light emitting device comprises at least one narrowband light source with a peak wavelength within a range selected from the group of 300 nm-350 nm, 350 nm-400 nm, 400 nm-450 nm, 450 nm-500 nm, 500 nm-550 nm, 550 nm-600 nm, 600 nm-650 nm, 650 nm-700 nm, 700 nm-750 nm, 750 nm-800 nm, and 800 nm-1200 nm. The light sources may be chosen to match the spectral qualities of red, green and blue such that collectively when used in a light emitting device, the color may be dialed in to achieve a desired color. In one embodiment, at least one light source is an LED package comprising a red, green, and blue LED capable of emitting light with a white color when each are emitting light. In another embodiment, the LED is a blue or ultraviolet LED combined with a phosphor. In another embodiment, a light emitting device comprises a light source with a first activating energy and a wavelength conversion material which converts a first portion of the first activating energy into a second wavelength different than the first. In another embodiment, the light emitting device comprises at least one wavelength conversion material selected from the group of a fluorophore, phosphor, a fluorescent dye, an inorganic phosphor, photonic bandgap material, a quantum dot material. In another embodiment, the light emitting device comprises white LED light sources. In another embodiment, the light sources comprise LEDs that are at least one selected from the group of: warm white, cool white, neutral white, daylight white, have a correlated color temperature between 2200 K and 2900 K, have a correlated color temperature between 2900 K and 3600 K, have a correlated color temperature between 3600 K and 4500 K, have a correlated color temperature between 4500 K and 4900 K, and have a correlated color temperature between 4900 K and 6600 K.

### Shape of Light Emitting Device

In one embodiment, the shape of the light emitting device is substantially in the shape of the character “U.” In one embodiment, the shape comprises three linear sections, with one section oriented at an angle (90 degrees, for example) to two parallel sections. In one embodiment, the light emitting devices comprises an arcuate light emitting region positioned between two linear light emitting regions. In one embodiment, the total length of the light emitting device is one selected from the group: 20-30, 25-35, 30-40, 35-45, 40-50, 45-55, 50-60, 55-65, 60-70, and 65-75 centimeters in length from the base pins to the outer surface of the arcuate light emitting region. In one embodiment, the ends of the light emitting device comprise medium bi-pin (G13) bases. In another embodiment, the light emitting device comprises miniature T-5 lamp bi-pin bases, medium T-8 lamp bi-pin bases, or medium T-12 lamp bi-pin bases. In one embodiment, the cross-section of the light emitting device is substantially circular. In another embodiment, the diameter of the cross section is substantially 1.5 inch or 1 inch. In one embodiment, the spacing between the linear tubular regions at the base or other region is greater than or equal to about one selected from the group 1.5, 3, and 6 inches. In a further embodiment, the total length of the curved light emitting region of the light emitting device is greater than one selected from the group of 100 mm, 150 mm, 300 mm, 400 mm, 500 mm, 600 mm, 700 mm, 900 mm, 1 meter, 1.2 meters, 1.4 meters, 1.6 meters, 1.8 meters, 2 meters, 2.2 meters, and 2.4 meters. In another embodiment, the total length of the curved light emitting region of the light emitting device is one selected from the group of: between 560 and 600 millimeters, between 1170 and 1300 millimeters, and between 2340 and 2600 millimeters. In one embodiment, the light emitting device comprises first and second linear light emitting tube sections parallel to each other and a third linear light emitting tube section orthogonal to the first and second linear light emitting tube sections. In another embodiment, the light emitting device comprises first and second linear light emitting tube sections parallel to each other and a third non-emitting linear tube section orthogonal to the first and second linear light emitting tube sections.

In one embodiment, the light emitting device comprises three linear sections and two couplers that operatively couple two parallel linear sections to a third linear section orthogonal to the first two parallel linear sections. In one embodiment, the coupler comprises two openings oriented 90 degrees to each other into which two linear sections are positioned. In another embodiment, the coupler comprises a coupler arcuate region along at least one side in a plane comprising the two linear sections extending into the coupler. For example, one or more couplers may comprise a 90 degree elbow comprising polyvinyl chloride (PVC).

In one embodiment, the first tube, second tube, and third tube of the light emitting device are positioned to substantially form the shape of a character “U” in a plane perpendicular to the optical axis. In another embodiment, the light emitting device may be substantially in the shape of the character “␣” while comprising a support bar (with a smaller dimension or diameter than the tube sections) in a region near the electrical connectors (such as bi-pin base connectors). In one embodiment, the support bar is a linear section physically coupled to the two parallel linear sections that provide increased rigidity and stability for the light emitting device. In one embodiment, the support bar is near an end of the light emitting device opposite the third tube. The support bar may comprise a polymer, metal, ceramic, or combination thereof.

### Radius of Curvature of Arcuate Region

In one embodiment, the radius of curvature of the arcuate region of the light emitting device is selected from the group 20-90, 20-80, 20-30, 40-50, 50-60, 60-70, 70-80, 80-90, 90-100, and 100-110 millimeters. In one embodiment, the radius of curvature of the arcuate region is about 97 millimeters and the length is about 560 millimeters. In one embodiment, the radius of curvature of the arcuate region is greater than 40 millimeters. In one embodiment, the arcuate region comprises light emitting diodes. In another embodiment, one or more couplers comprise one or more arcuate regions.

### Circuit Board

In one embodiment, the LEDs of the light emitting device are disposed upon a single circuit board. In one embodiment, the circuit board is shaped substantially like the character “U”. In another embodiment, the light emitting device comprises a plurality of circuit boards. In another embodiment, the light emitting device comprises a curved circuit board and one or more linear circuit boards. In another embodiment, the light emitting device comprises two curved circuit boards. In another embodiment, the light emitting device comprises three linear circuit boards.

### Pitch of the Light Sources

In one embodiment, the light emitting device comprises an array of LEDs with an average density greater than one selected from the group of: 2, 3, 4, 5, 6, 7, 8, 9, and 10 LEDs per linear inch. In one embodiment, a curved light emitting device comprises a curved array of LEDs with an average pitch, P, disposed parallel to a linear direction of the array of LEDs in the linear light emitting region of the light emitting device. In one embodiment, the pitch, P, is less than one selected from the group of 10 mm, 8 mm, 6 mm, 5 mm, 4 mm, 3 mm, and 2 mm. In one embodiment, within the linear light emitting region, the average ratio of the dimension in the linear direction of the LED to the average spacing between the LEDs in the linear direction is one selected from the group: 0.5-3.0, 0.5-1.0, 0.8-1.0, 1.0-1.2, 1.2-1.4, 1-1.5, 1.0-2.0, and 1.0-3.0. In another embodiment, the average ratio of the dimension in the linear direction of the LED to the average spacing between the LEDs in the linear direction is less than 5.

In another embodiment, the average spacing between the LEDs, D, is one selected from the group: 0.1 to 0.5, 0.5 to 1.0, 1.0-1.5, 1.2-1.8, 1.5-2.0, and 1.8-2.2 millimeters. In another embodiment, the average ratio of the dimension of the LED oriented closest to the direction of the arc at the LED to the average spacing between the LEDs along the arc is one selected from the group: 0.5-3.0, 0.5-1.0, 0.8-1.0, 1.0-1.2, 1.2-1.4, 1-1.5, 1.0-2.0, and 1.0-3.0.

### Orientation of the Light Sources

In one embodiment, the light emitting device comprises a curved array of rectangular LEDs with a first dimension in a first direction orthogonal to the optical axis of the light emitted from the LED longer than a second dimension in a second direction orthogonal to the first direction and orthogonal to the optical axis of the light emitted from the LED, wherein the LEDs are positioned with their second dimension substantially parallel to the linear direction of the linear region disposed between the base and the arcuate region and at least one LED within the arcuate region is positioned with its second dimension oriented at an angle greater than zero to the linear direction. In one embodiment, the orientation of two or more LEDs changes along the arcuate light emitting region of the light emitting device. In one embodiment, the arcuate light emitting region comprises an LED oriented orthogonal in a plane orthogonal to the optical axis of the LED to the orientation of an LED in the linear light emitting region.

### Spatial Uniformity of Light Emitting Region

In one embodiment, the light emitting device has a spatial luminance profile with a curved bright region with a substantially uniform luminance along the surface of the light transmitting cover positioned above the linear array of LEDs or the curved array of LEDs. In one embodiment, the luminance uniformity, U, measured at the surface of the light transmitting cover along the linear array section or the curved array section above the array of LEDs, is greater than one selected from the group: 60%, 70%, 80%, 85%, 90%, and 95% with the uniformity, U, defined by the equation:

$$U = \frac{{L}_{min}}{{L}_{max}}$$

where Lₘᵢₙ is the average minimum luminance along the light emitting surface and Lₘₐₓ is the average maximum luminance along a surface of the light emitting surface when measured with a 5 mm or greater spot size. In one embodiment, the light transmitting cover is substantially clear and has a haze less than 10%. In another embodiment, the light transmitting cover is diffuse and has a haze (when flattened to a non-arcuate shape by thermoforming and/or pressure and measured according to ASTM D1003) greater than one selected from the group of 10%, 20%, 30%, 40%, 50%, 60%, 70%, 80%, and 90%. In the haze measurements, when the sample is arcuate, the sample is flattened by thermoforming, pressure, or a combination thereof such that the optical properties do not substantially change in the direction normal to the surface, but the overall shape is substantially flat to be measured according to ASTM D1003 using a BYK Gardner haze meter. In another embodiment, the light transmitting cover comprises a phosphor region disposed to receive blue and/or ultraviolet light and convert a percentage of incident light into light of a different wavelength such that the combination of the blue and/or UV light with the converted light output is substantially white.

### Power Source

In one embodiment, the light emitting device is powered by an electrical signal selected from the group of 12V DC, 12V AC, ˜110-120V AC, ˜220-240V AC, switchable power supply, 28V DC power supply, AC power supply, DC power supply, and 3V DC power supply. In one embodiment, the power is provided by a craft such as an automobile, aircraft, or watercraft. In another embodiment, the power supply is a battery supply, or the light emitting device has a backup battery based power supply. In another embodiment, the light emitting device comprises a solar cell and a battery such that the battery can be charged by exposure to light such as sunlight and energy is stored in the battery for future use. In one embodiment, the light emitting device is a curved LED tube for replacement of a U-shaped fluorescent tube in a fixture and comprises an LED driver disposed within the heat sink tube with an electrical connection to the LEDs and an electrical connection to the electrical connection pins of the light emitting device.

### Secure and Removable Connector

In one embodiment, a light emitting device comprises a aluminum tube heat sink, an array of LEDs disposed on a circuit board and thermally coupled to the aluminum tube heat sink, an LED driver that converts AC electrical power into DC power to drive the LEDs, electrical connection pins, and a secure and removable connector means comprising a female connector, a male connector and a fastener such as, without limitation, a cable tie. In this embodiment, the leads from the electrical connection pins at one or both ends of the tube may be electrically coupled to the LED driver by the removable connector means. Also, in this embodiment, the leads to circuit board comprising the LEDs may be electrically coupled to the LED driver by the removable connector means. In one embodiment, the two leads from the AC power (and the electrical connectors such as pins) are connected to a female electrical connector and the two leads connected to the LED driver are connected to a male electrical connector electrically coupled into the female connector. In this embodiment, the cable tie can be extended around the female and male connector between the two leads from the AC power and between the two leads connected to the LED driver. In this embodiment, by placing the cable tie between the leads on the male and the female connector, the cable tie will not slide off of the two connectors it is holding together. Furthermore, in this embodiment, the cable tie can securely couple the female and male connector together. In addition, by cutting the cable tie, the connectors can be easily separated such that the LED driver can be replaced, for example. In another embodiment, the light emitting device comprises a secure and removable connector means between the LED driver and the power source and the LED driver and the LEDs such that the driver may be easily replaced by cutting the fasteners and separating the connectors. In one embodiment, the fastener is a cable tie (also known as a zip tie and tie wrap). In a further embodiment, the fastener is disposed to physically couple the male and female connectors to form an electrical connection and is one selected from the group of belt hook, rapstrap fastener, metal buckle clip, strap, snap, ring, pin, plastic cable tie, tear-away-tie, and reusable cable tie. In another embodiment, the male and female connectors are one selected from the group of: quick connect terminals, fork connectors, disconnects, fully insulated, partially insulated, locking fork, quick disconnect, and wire terminals.

### Groove and Extension for Cover Seal

In one embodiment, the light emitting device comprises a linear groove in a heat sink or housing element and light transmitting cover with an extension that can slide into or snap into the groove to provide a seal. In one embodiment, an aluminum heat sink tube comprises a groove on opposite sides of the tube and a light transmitting cover comprises an extension disposed on opposite sides such that when the extensions are slid or snapped into the groove, a water or moisture resistant seal is formed between the light transmitting cover and the heat sink. In a further embodiment, a gasket (such as a rubber strip) is disposed within the groove such that the seal between the light transmitting cover and the heat sink has a higher water or moisture resistance.

### Groove in the Housing or Heat Sink

In one embodiment, the groove disposed in the housing of the light emitting device or the tube heat sink of the light emitting device extends substantially along the curved shape of the light emitting area of the light emitting device. In another embodiment, the groove has an opening width, G_{w}, selected from the group of: between 0.5 mm and 10 mm, between 0.5 mm and 5 mm, between 0.5 mm and 2 mm, and between 0.5 mm and 1.5 mm. In another embodiment, the groove has a uniform depth, G_{d}, selected from the group of: between 0.5 mm and 10 mm, between 0.5 mm and 5 mm, between 0.5 mm and 2 mm, and between 0.5 mm and 1.5 mm. In another embodiment, the groove has a non-uniform depth, with the depth on a first side, G_{d1}, selected from the group of: between 0.5 mm and 10 mm, between 0.5 mm and 5 mm, between 0.5 mm and 2 mm, and between 0.5 mm and 1.5 mm; and the depth on a second side, G_{d2}, selected from the group of: G_{d1}+0.5 mm, G_{d1}+1 mm, G_{d1}+1.5 mm, G_{d1}+2 mm, G_{d1}+2.5 mm, G_{d1}+3.5 mm, G_{d1}+4 mm, G_{d1}+T1 (where T1 is the average thickness of the light transmitting cover near the extension), and between G_{d1}+(0.9×T1) and G_{d1}+(1.1×T1). In another embodiment, the groove depth is non-uniform in the plane perpendicular to the linear direction of the linear light emitting region, and the light transmitting cover and heat sink form a shape with a cross-section with an outer surface substantially that of a circle. In another embodiment, the light transmitting cover and heat sink form a shape with a cross-section with an outer surface substantially that of a circle except for micro ridges in the section of the heat sink.

### Extension in Light Transmitting Cover

In one embodiment, the extension in the light transmitting cover of the light emitting device has a depth, d, selected from the group of: between 0.5 mm and 10 mm, between 0.5 mm and 5 mm, between 0.5 mm and 2 mm, between 0.5 mm and 1.5 mm, greater than 0.5 mm, and less than 10 millimeters. In another embodiment, the extension in the light transmitting cover of the light emitting device has a height, h, selected from the group of: between 0.5 mm and 10 mm, between 0.5 mm and 5 mm, between 0.5 mm and 2 mm, between 0.5 mm and 1.5 mm, greater than 0.5 mm, and less than 10 millimeters.

### Waterproof

In one embodiment, the light source and electrical components are substantially sealed by at least one of an epoxy, resin, rubber, silicone, or polymer such that the electrical components are waterproof to a depth selected from the group of 5 feet, 10 feet, 20 feet, 30 feet, 50 feet, 100 feet, and 200 feet. In another embodiment, the light emitting device components satisfy the United Laboratories UYMR2 standards for components and fittings intended for use in electric signs and accessories. In another embodiment, the light emitting device continues to operate after a 12 hour continuous salt spray test. In another embodiment, the light emitting device continues to operate after a 24 hour continuous salt spray test. In one embodiment, the light emitting device continues to operate after a 48 hour continuous salt spray test. In one embodiment, the light emitting device continues to operate after a 60 hour salt water soak test. In one embodiment, the light emitting device continues to operate after a 120 hour salt water soak test. In another embodiment, the light emitting device continues to operate after a 240 hour salt water soak test.

The following are more detailed descriptions of various embodiments illustrated in the Figures.

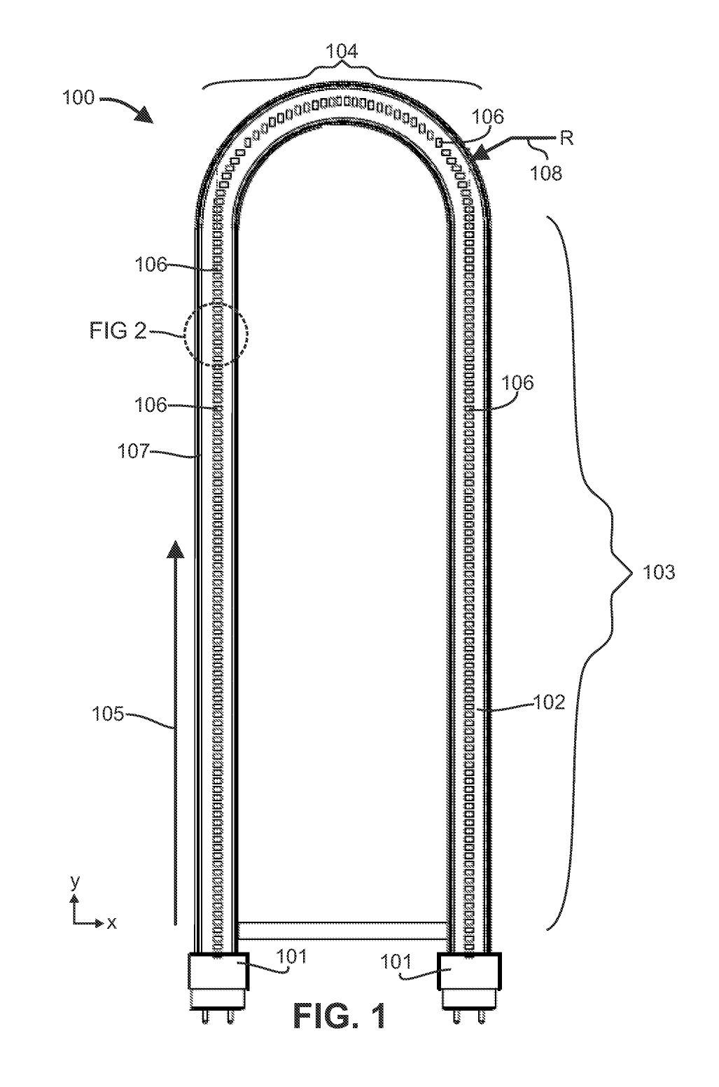

FIG. 1 is a bottom view of an embodiment of an embodiment of a light emitting device 100 in the form of a U-shaped LED tube comprising an arcuate light emitting region 104 positioned between two linear light emitting regions 103 and a curved array of LEDs 106 positioned below a curved circuit board 102. The light emitting device 100 comprises two bi-pin bases 101 configured to receive electrical power for the light emitting device 100. A light transmitting cover 107 is disposed above the curved array of LEDs 106 to transmit the light received from the LEDs 106 out of the light emitting device 100. The arcuate light emitting region 104 has radius of curvature 108 of R and the linear light emitting regions 103 of the curved array of LEDs 106 extend in a linear direction 105 (y direction) from the bi-pin bases 101. In the embodiment shown in FIG. 1, the LEDs 106 are rotated in the x-y plane in the arcuate light emitting region 104 relative to the linear light emitting region 103. The light emitting device 100 shown in FIG. 1 may be used to replace a U-shaped fluorescent bulb in a light fixture.

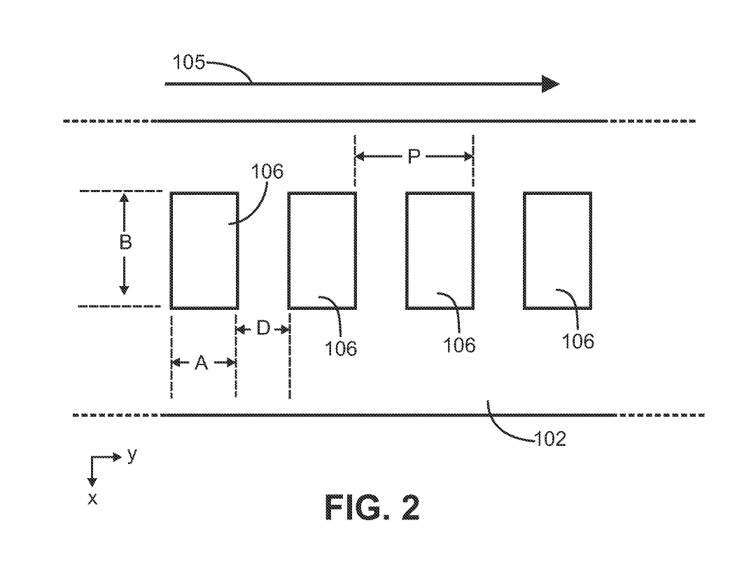

FIG. 2 is a bottom view of a portion of the linear light emitting region 103 of the light emitting device 100 of FIG. 1 comprising the array of LEDs 106 with a pitch, P, disposed below a circuit board 102. The LEDs 106 are substantially rectangular and positioned with their shorter dimension, A, parallel to the linear direction 105. The longer dimension, B, of the LEDs 106 is positioned substantially orthogonal to the linear direction 105. The spacing, D, between the LEDs 106, in the embodiment shown in FIG. 2, is less than the shorter dimension, A, of the LEDs 106.

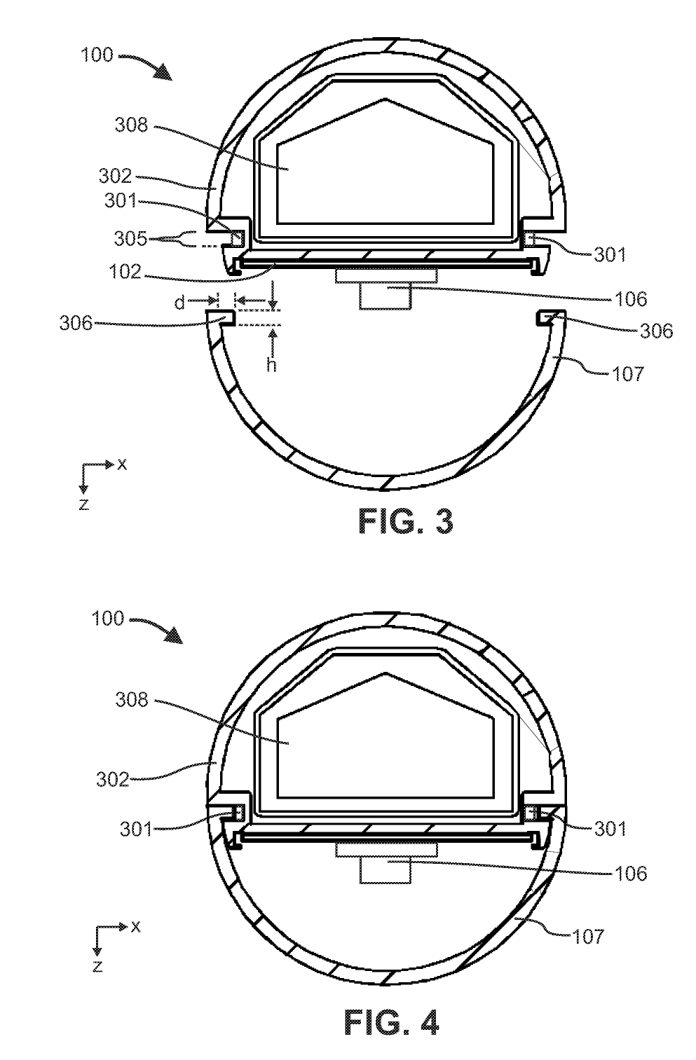

FIG. 3 is a cross-sectional view of the light emitting device 100 of FIG. 1. An aluminum heat sink tube 302 comprises an LED driver 308 within the interior and the LEDs 106 are disposed below a circuit board 102 that is thermally coupled to the aluminum heat sink tube 302 by a thermally conductive adhesive. The aluminum heat sink tube 302 further comprises two grooves 305 disposed parallel to the linear direction (out of the page) along each side. The grooves 305 are disposed to receive the extensions 306 in the light transmitting cover 107 with a substantially arcuate cross section. The extensions 306 have a lateral length, d, in the x direction and a height, h, in the z direction such that the extensions 306 can be snapped or slid into place in the groove 305. In the embodiment shown in FIG. 3, the grooves 305 further comprise a gasket 301 (optional) to further reduce water penetration into the light emitting device 200 when submersed or exposed to damp conditions.

FIG. 4 is a cross sectional view of the light emitting device 100 of FIG. 1 with the light transmitting cover 107 attached such that the extensions 306 are disposed in the grooves 305. In this embodiment, the aluminum heat sink tube 302 and the light transmitting cover 303 provide a seal to reduce or prevent water or moisture penetration into the electrical components within the light emitting device 100.

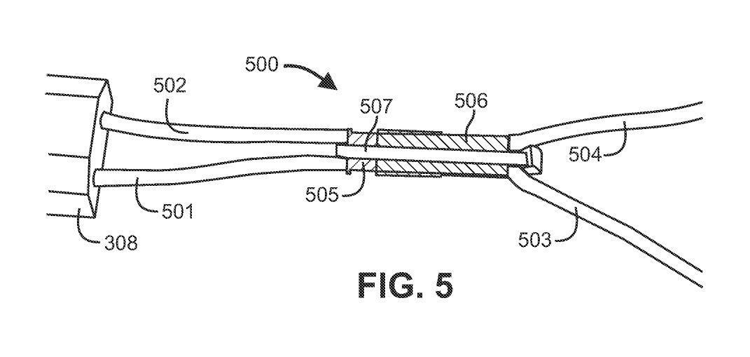

FIG. 5 is a perspective view of an embodiment of a secure and removable connector means 500 for connecting a first plurality of leads (501 and 502) to a second plurality of leads (503 and 504) using a male connector 505, a female connector 506 and a cable tie 507. The cable tie 507 is fastened between the leads 501 and 502 and between the leads 503 and 504. The leads 502 and 503 are disposed to provide AC electrical power to the LED driver 308. In this embodiment, the cable tie 507 securely holds the male connector 505 and female connector 506 together and the cable tie 507 can be cut to allow the LED driver 308 for a light emitting device to be changed or replaced.

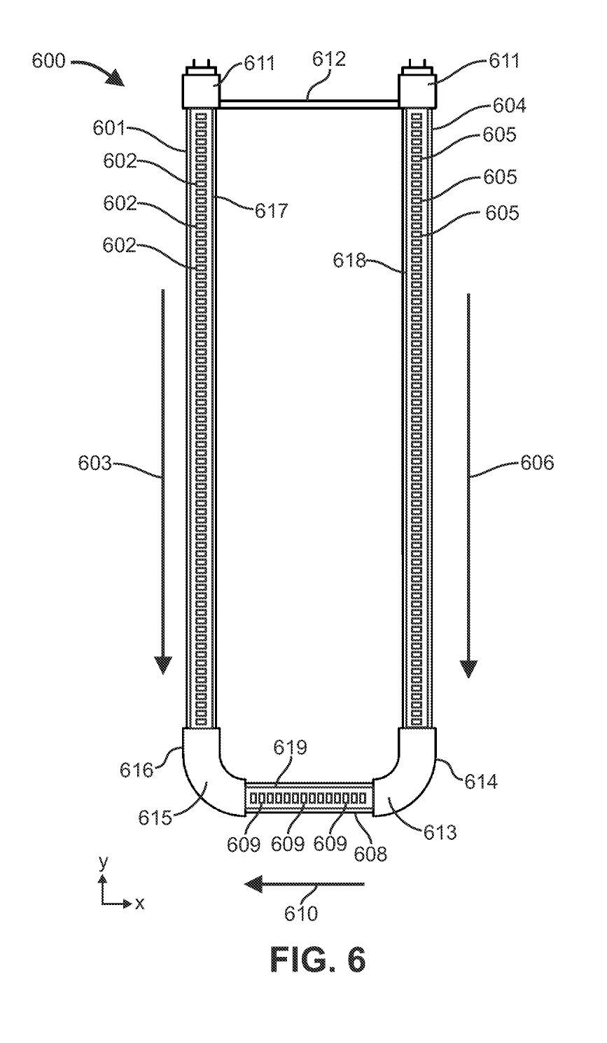

FIG. 6 is a bottom view of an embodiment of a light emitting device 600 comprising three linear tubes 601, 604, and 608. The first tube 601 comprises a first light transmitting cover 617 and a first linear array of light emitting diodes 602 with the array oriented in a first direction 603. The second tube 604 comprises a second light transmitting cover 618 and a second linear array of light emitting diodes 605 with the array oriented in a second direction 606 parallel to the first direction 603. The third tube 608 comprises a third light transmitting cover 619 and a third linear array of light emitting diodes 609 with the array oriented in a third direction 610 orthogonal to the first direction 603 and the second direction 606. In the embodiment shown in FIG. 6, the tubes 601, 604, and 608 comprise linear arrays of light emitting diodes 602, 605, and 609 that are 1×N arrays where N is the number of light emitting diodes in the array direction. The first tube 601, the second tube 604, and the third tube 608 of the light emitting device 600 are positioned to substantially form the shape of a character “U” in a plane (x-y plane) perpendicular to the optical axis (+z axis).

The first linear array of light emitting diodes 602 are rectangular in shape with a shorter dimension in the y direction than in the x direction and are positioned with their optical axis parallel to the +z direction (out of the page) such that light from the first linear array of light emitting diodes 602 transmits through the first light transmitting cover 617 and the luminance uniformity at the first light transmitting cover 617 in the first direction 603 is greater than 60%. The second linear array of light emitting diodes 605 are rectangular in shape with a shorter dimension in the y direction than in the x direction and are positioned with their optical axis parallel to the +z direction (out of the page) such that light from the first linear array of light emitting diodes 605 transmits through the second light transmitting cover 618 and the luminance uniformity at the second light transmitting cover 618 in the second direction 606 is greater than 60%. The third linear array of light emitting diodes 609 are rectangular in shape with a shorter dimension in the x direction than in the y direction and are positioned with their optical axis parallel to the +z direction (out of the page) such that light from the third linear array of light emitting diodes 609 transmits through the third light transmitting cover 619 and the luminance uniformity at the third light transmitting cover 619 in the third direction 610 is greater than 60%.

The first tube 601 is physically coupled to the third tube 608 by a first 90 degree elbow coupler 615 with an arcuate region 616 in a plane comprising the first tube 601 and the third tube 608. The second tube 604 is physically coupled to the third tube 608 by a second 90 degree elbow coupler 613 with an arcuate region 614 in a plane comprising the second tube 604 and the third tube 608. The first tube 601 is physically coupled to the second tube 604 by a support bar 612 in a region near the electrical bi-pin base connectors 611 used to provide electrical power to the light emitting diodes 602, 605, and 609. In one embodiment, the couplers have substantially straight sides forming a sharp corner in the plane orthogonal to the optical axis of the light emitting diodes.

### EQUIVALENTS

Those skilled in the art will recognize, or be able to ascertain using no more than routine experimentation, numerous equivalents to the specific procedures described herein. Such equivalents are considered to be within the scope of the invention. Various substitutions, alterations, and modifications may be made to the invention without departing from the spirit and scope of the invention. Other aspects, advantages, and modifications are within the scope of the invention. The contents of all references, issued patents, and published patent applications cited throughout this application are hereby incorporated by reference. The appropriate components, processes, and methods of those patents, applications and other documents may be selected for the invention and embodiments thereof. This application is intended to cover any adaptations or variations of the specific embodiments discussed herein. Therefore, it is intended that this disclosure be limited only by the claims and the equivalents thereof.

Unless otherwise indicated, all numbers expressing feature sizes, amounts, and physical properties used in the specification and claims are to be understood as being modified by the term “about”. Accordingly, unless indicated to the contrary, the numerical parameters set forth in the foregoing specification and attached claims are approximations that can vary depending upon the desired properties sought to be obtained by those skilled in the art utilizing the teachings disclosed herein. Unless indicated to the contrary, all tests and properties are measured at an ambient temperature of 25 degrees Celsius or the environmental temperature within or near the device when powered on (when indicated) under constant ambient room temperature of 25 degrees Celsius.

What is claimed is:

1. A light emitting device comprising:
a. a first tube with a first linear section comprising a first linear array of light emitting diodes in a first direction with an optical axis and a density greater than 5 light emitting diodes per linear inch, the first tube comprising a first light transmitting cover positioned to receive and emit light from the first linear array of light emitting diodes;
b. a second tube with a second linear section comprising a second linear array of light emitting diodes in a second direction with a density greater than 5 light emitting diodes per linear inch, the second tube is separated from the first tube in a third direction orthogonal to the first direction, the second linear section of the second tube is substantially parallel to the first linear section of the first tube, the second tube comprising a second light transmitting cover positioned to receive and emit light from the second linear array of light emitting diodes; and
c. a third tube physically coupled to the first tube and second tube,
wherein a luminance uniformity along the first direction measured at a light emitting surface of the first light transmitting cover of light from the first linear array of light emitting diodes is greater than 60%, and a luminance uniformity along the second direction measured at a light emitting surface of the second light transmitting cover of the light from the second linear array of light emitting diodes is greater than 60%.

2. The light emitting device of claim 1 wherein the cross-section of the first tube in a plane perpendicular to the first direction is substantially circular.

3. The light emitting device of claim 2 wherein the first linear array of light emitting diodes and the second linear array of light emitting diodes are positioned upon a contiguous circuit board.

4. The light emitting device of claim 1 wherein the first tube, the second tube, and the third tube of the light emitting device are positioned to substantially form the shape of a character “U” in a plane perpendicular to the optical axis.

5. The light emitting device of claim 1 wherein the first linear array of light emitting diodes has an average pitch less than 6 millimeters in the first direction.

6. The light emitting device of claim 5 wherein the first linear array of light emitting diodes comprises light emitting diodes substantially rectangular in shape in a plane orthogonal to the optical axis of the light emitting diodes with a first dimension in the plane in the first direction smaller than a second dimension in the plane in a direction orthogonal to the first direction.

7. The light emitting device of claim 6 wherein the first linear array of light emitting diodes has an average spacing between the light emitting diodes and a ratio of the first dimension to the average spacing is between 1 and 3.

8. The light emitting device of claim 1 wherein the first tube comprises only one linear array of light emitting diodes and the second tube comprises only one linear array of light emitting diodes.

9. The light emitting device of claim 1 further comprising a support bar physically coupled to the first tube and second tube near an end of the light emitting device opposite the third tube.

10. The light emitting device of claim 1 wherein the third tube comprises a third array of light emitting diodes.

11. The light emitting device of claim 10 wherein the third tube is substantially linear.

12. The light emitting device of claim 10 wherein the third tube has an arcuate shape in a plane comprising the third array of light emitting diodes.

13. The light emitting device of claim 12 wherein light emitting from the first linear array of light emitting diodes, the second linear array of light emitting diodes, and the third array of light emitting diodes is perceived as a single continuous curve of light by an individual with a visual acuity of 1 arcminute at a distance of 1 meter.

14. The light emitting device of claim 12 wherein the arcuate shape comprises a radius of curvature greater than 40 millimeters.

15. The light emitting device of claim 12 wherein the first linear array of light emitting diodes and the second linear array of light emitting diodes are positioned upon a contiguous circuit board substantially in the shape of a character “U” in a plane perpendicular to the optical axis.

16. A light emitting device comprising:
a. a first linear tube section comprising a first linear array of light emitting diodes arrayed in a first direction orthogonal to an optical axis of the light emitting diodes, the light emitting diodes of the first linear array of light emitting diodes have a first dimension in the first direction shorter than a second dimension in a direction orthogonal to the optical axis and the first direction;
b. a second linear tube section oriented parallel to the first linear tube section comprising a second linear array of light emitting diodes arrayed in a second direction, the second linear tube section separated from the first linear tube section by at least 1.5 inches in a third direction orthogonal to the first direction; and
c. a third tube section coupled to the first linear tube section and the second linear tube section,
wherein the first linear array of light emitting diodes has an average spacing between the light emitting diodes, and a ratio of the first dimension to the average spacing is between 1 and 3.

17. The light emitting device of claim 16 wherein the first linear tube section further comprises a light transmitting cover positioned to receive light from the first linear array of light emitting diodes and a heat conducting member thermally coupled to the first linear array of light emitting diodes, wherein the heat conducting member comprises a first pair of grooves positioned parallel to the first direction and on opposite sides of the first linear array of light emitting diodes, and the first light transmitting cover comprises a first pair of extensions positioned within the first pair of grooves.

18. The light emitting device of claim 17 wherein the first linear array of light emitting diodes are protected from exposure to water when the light emitting device is immersed in water to a depth of 5 feet.

19. The light emitting device of claim 16 wherein the first tube, the second tube, and the third tube of the light emitting device are positioned to substantially form the shape of a character “␣” in a plane perpendicular to the optical axis.

20. A method of manufacturing a light emitting device comprising:
a. positioning a first linear array of light emitting diodes in a first direction on a first circuit board in a first tube such that the first linear array of light emitting diodes has an average pitch less than 6 millimeters in the first direction;
b. positioning a second linear array of light emitting diodes in a second direction parallel to the first direction on a second circuit board in a second tube;
c. spacing the first tube from the second tube in a third direction orthogonal to the first direction;
d. operatively coupling the third tube to the first tube and the second tube; and
e. positioning a first light transmitting cover to receive and emit light from the first linear array of light emitting diodes and positioning a second light transmitting cover to receive and emit light from the second linear array of light emitting diodes such that a luminance uniformity along the first direction measured at a light emitting surface of the first light transmitting cover of light from the first linear array of light emitting diodes is greater than 60%, and a luminance uniformity along the second direction measured at a light emitting surface of the second light transmitting cover of light from the second linear array of light emitting diodes is greater than 60%.
